(19) United States
(12) Patent Application Publication
(10) Pub. No.: US 2025/0087511 A1
(43) Pub. Date: Mar. 13, 2025

(54) METHOD FOR DETERMINING A CENTER POSITION OF A TRANSFERRED SEMICONDUCTOR PART AND A SYSTEM FOR DETERMINING THE SAME

(71) Applicant: VM Inc., Icheon-si (KR)

(72) Inventors: Tae Jin KWON, Anseong-si (KR); Woo Hyung CHOI, Seongnam-si (KR); Sang Woo LEE, Suwon-si (KR)

(21) Appl. No.: 18/789,596

(22) Filed: Jul. 30, 2024

(30) Foreign Application Priority Data
Sep. 7, 2023 (KR) 10-2023-0118991

(51) Int. Cl. H01L 21/67; H01L 21/683

(52) U.S. Cl. CPC H01L 21/67259; H01L 21/6838; H01L 21/6831

(57) ABSTRACT

Provided is a method for determining a center position of a transferred semiconductor part including: disposing at least one pair of component detecting sensors at a transferring path of the semiconductor part; detecting different portions of the semiconductor part by each component detecting sensor; calculating a centering position of the semiconductor part based on the detected different portions; and fixing the semiconductor part at a designated position based on the calculating result.

### BACKGROUND OF THE INVENTION

### Field of the Invention

The present invention relates to a method for determining a center position of a transferred semiconductor part and a system for determining the same, in particular the method for determining the center position of the transferred semiconductor part to be transferred and to be fixed at a designated position for processing and the system for the same.

### Description of the Related Art

A pattern for achieving a high integrating level and a high efficiency of a semiconductor element is gradually changing minutely, and a performance is being developed by applying various materials. At the same time, the pattern becomes gradually more detailed and the structure becomes more complex and deeper. As a result of this, the number of total processes and a level of difficulty are increasing rapidly. It is required essentially to maintain and enhance a yielding rate of a wafer in order to proceed a process considering a productivity of a process with a higher level of difficulty, and accordingly a uniformity of the total process, a production per unit time and a process profile formation are emphasized as a competitiveness of a process equipment. Many semiconductor equipment manufacturers are making effort for improving corresponding main performance through developing various conditions such as an enhancement of a temperature uniformity, a control of a plasma density or a control of a sheath area. Recently, a process performance impact such as a correlation among a temperature of a substrate, a temperature of an electrostatic chuck below the substrate and a portion around the substrate and a physical position is emphasized as a major factor among the above matters, and an improvement and a development of a related technology are being developed. And also, a relationship between a location of a wafer substrate on the electrostatic chuck and a fine location of a part around of the substrate may be major factor for determining a yielding rate of a substrate edge in ration to a fluid flow according to the above mentioned temperature and structure, and accordingly a technology for adjusting a position of the substrate is being developed.

The known method for designating a position of a robot arm in course of transferring a wafer has a possibility of generating particles, because a module where the robot for transferring the wafer is located as well as the related chamber is opened as the state of the chamber is changed from a vacuum state into an atmosphere pressure. Thereby, the method has a problem that the entire system may be shut down to result in a worse effect on productivity because of a long time for returning to a normal state. And also, it has a possibility to generate another problem below. As a dedicated tool should be manufactured for adjusting a position of the robot arm in course of designating a seating position of the water or the adjusting process should be performed visually, the work takes a long time and the process gets complicated, which may cause a problem to generate a deviation depending on a worker or a chamber where the work is performed. A worker exposed to a rapid movement of the robot should pay particular attention to safety, and an individual training for using a related tool is required additionally because the task is very difficult. The work for adjusting a transferring position of the wafer belongs to one essential course for setting up an equipment firstly, and the work seems to require no additional work. However, when a problem happens in a wafer transferring system or a process uniformity is not consistent, the work should be checked first of all, therefore, the importance and the frequency of the work is relatively high.

A known technology has applied a method for determining a center position of a wafer using an optical sensor. The sensor may be located at a position where the wafer transferring robot is connected to a chamber of a transferring module for verifying a difference of the wafer center in course of entering and exiting the process chamber. And also, when a deviation from the wafer center happens, an alarm may be generated for making an inspection, the position of the wafer center may be detected in such way according to the known technology. However, the transferring module is a module different from the process module, and a relative position of two modules is not constant physically from time to time. As a result of this, the sensor position of the transferring module and the electrostatic chuck position within the chamber may be different depending on the chamber, and thereby it is difficult for one data to be applied to verifying a position of the wafer in different chambers.

The present invention for solving the known technology has an object as following.

### PURPOSE OF THE INVENTION

The purpose of the present invention is to provide with a method for determining a center position of a transferred semiconductor part and a system for determining the same, wherein two different portions of a semiconductor part are detected using at least two sensors and a center position of the semiconductor part, a transferring direction and a tilting angle are to be detected, thereby the semiconductor part can be placed at a designated position.

### SUMMARY OF THE INVENTION

In one embodiment of the present invention, a method for determining a center position of a transferred semiconductor part comprises disposing at least one pair of component detecting sensors at a transferring path of a semiconductor part; detecting different portions of the semiconductor part by each component detecting sensor; calculating a centering position of the semiconductor part based on the detected different portions; and fixing the semiconductor part at a designated position based on the calculating result.

In other embodiment of the present invention, the at least one pair of component detecting sensors are disposed at a process chamber where the semiconductor component is secured.

In another embodiment of the present invention, wherein the semiconductor part is a wafer or an edge ring.

In still another embodiment of the present invention, the different portions are located at both parts of a component bisector corresponding to the transferring path of the semiconductor part.

In still another embodiment of the present invention, a height from a reference surface is measured by each component detecting sensor.

In still another embodiment of the present invention, a system for determining a center position of a transferred semiconductor part comprises a transferring robot for transferring the semiconductor part; a pair of component detecting sensors disposed at a process chamber for a process of the semiconductor part; and a component location determining module for determining a center position of the semiconductor part based on two pairs of positions detected by each component detecting sensor.

In still another embodiment of the present invention, three dimensional coordinates R, θ, Z are determined by the component location determining module for calculating a distance along a transferring direction of the component, a rotating angle based on the transferring direction, a height and an inclination.

In still another embodiment of the present invention, the semiconductor part is a wafer or an edge ring, and the semiconductor part is transferred from a transferring module 23 to a process chamber.

### BRIEF DESCRIPTION OF THE DRAWINGS

FIG. 1 shows an embodiment of a method for determining a center position of a transferred semiconductor part according to the present invention.

FIG. 2 shows an embodiment of a system for determining a center position of a transferred semiconductor part according to the present invention.

FIG. 3 shows other embodiment a system for determining a center position of a transferred semiconductor part according to the present invention.

FIG. 4 shows an embodiment of a process for fixing a semiconductor part at a designated position after the part is transferred from a transferring module to a process chamber.

FIG. 5 shows an embodiment of a method for managing an operating error of a transferring robot according to the present invention.

### DETAILED DESCRIPTION OF EXEMPLARY EMBODIMENTS

FIG. 1 shows an embodiment of a method for determining a center position of a transferred semiconductor part according to the present invention.

Referring to FIG. 1, a method for determining a center position of a transferred semiconductor part comprises disposing at least one pair of component detecting sensors at a transferring path of the semiconductor part P11; detecting different portions of the semiconductor part by each component detecting sensor P12; calculating a centering position of the semiconductor part based on the detected different portions P13; and fixing the semiconductor part at a designated position based on the calculating result P14.

The semiconductor part may be a wafer or an edge ring that is transferred from an outside to an inside of a process chamber, and is fixed at a designated position in the process chamber. For example, the semiconductor part may be transferred from the transferring module to the process module such as a vacuum chamber by a vacuum transferring module robot (VTM robot). The pair of component detecting sensors may be disposed at the transferring path of the semiconductor part, preferably disposed at the same area as the area where the semiconductor partis fixed. For example, the wafer corresponding to the semiconductor part may be transferred from the transferring module to the vacuum chamber corresponding to the vacuum module.

And the pair of component detecting sensors may be disposed at the transferring path of the wafer in the vacuum module, and the wafer may be fixed at a vacuum chuck. The pair of component detector sensors may be disposed separately from each other in a direction perpendicular to the transferring path of the semiconductor part. And different parts of the semiconductor part may be detected by the pair of component detecting sensors disposed at this path P12. For example, a first component of the semiconductor part may be detected by a first component detecting sensor, and a second component of the semiconductor part may be detected by a second component detecting sensor. If in this way, the different components of the semiconductor part are detected, then a center position of the semiconductor part may be calculated from the detected information P13. For example, when the semiconductor part becomes a wafer with a circular shape in general, different parts of the wafer in course of transferring may be detected by the pair of component detecting sensors. Each time taken for being detected by each component detecting sensor is calculated, and each chord length formed by each transferring path may be calculated since a transferring velocity of the wafer is predetermined. If two chord lengths are the same, it means that the wafer center passes through a midpoint of a straight line connecting the pair of component detecting sensors. In contrast, if two chord lengths are different from each other, then the wafer center deviates from the midpoint. And a deviation degree may be calculated by comparing two chord lengths. In this way, the center position of the semiconductor part from the detection information may be obtained by the pair of component detecting sensors.

Selectively a vertical length to the semiconductor part from a reference surface may be detected by each component detecting sensor. If the semiconductor part such as the wafer is transferred parallel to a reference surface, then vertical distances detected by the pair of component detecting sensors should have the same value. In contrast, if the semiconductor part is transferred in a tilted state, then two vertical distances measured by the pair of component detecting sensors may be different from each other. When the center position of the semiconductor part is calculated in this way, the semiconductor part can be fixed in a determined position based on the calculated position P14. For example, the wafer may be fixed at an electrostatic chuck of a process chamber. If the center of the wafer deviates from the center of the electrostatic chuck, the deviating degree may be calculated from the detected information obtained by the pair of the component detecting sensors. And then, the position of the wafer may be corrected according to the calculating result, and the wafer can be fixed at the electrostatic chuck according to the corrected value. Accordingly, the center of the wafer can be located at the center of the electrostatic chuck. An embodiment of detecting the center position of the wafer by the pair of component detecting sensors is explained below.

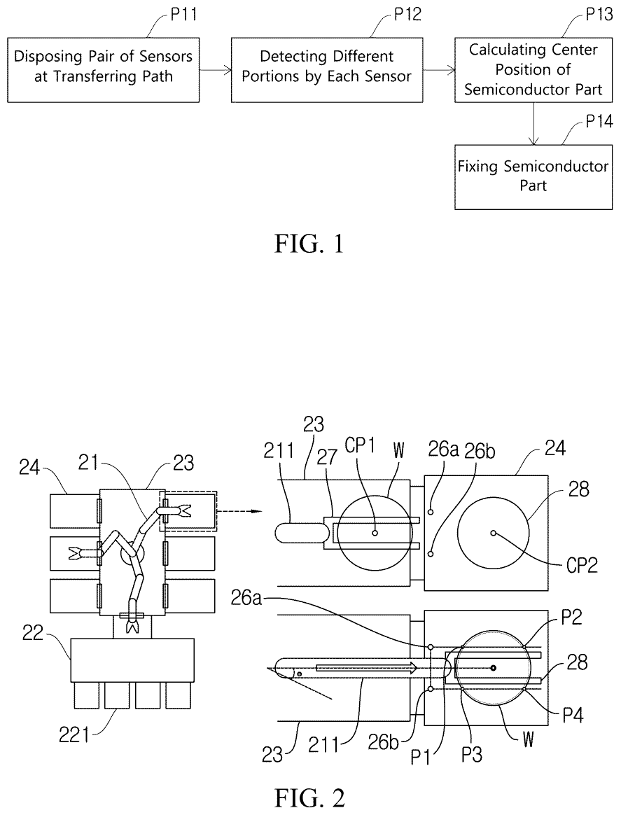

FIG. 2 shows an embodiment of a system for determining a center position of a transferred semiconductor part according to the present invention.

Referring to FIG. 2, a system for determining a center position of a transferred semiconductor part comprises a transferring robot 21 for transferring the semiconductor part; a pair of component detecting sensors 26a, 26b disposed at a process chamber 24 for a process of the semiconductor part; and a component location determining module for determining a center position of the semiconductor part based on two pairs of positions P1, P2, P3, P4 detected by each sensor consisting of the pair of sensors 26a, 26b. When the wafer W is loaded on a EFEM (Equipment Front End Module) 22 from a LPM (Load Port Module) 221, The wafer may be transferred to a TM (Transfer Module) 23 by a VTM Robot (Vacuum Transfer Module) 21. And then, a gate valve opens to transfer the wafer from the TM 23 to a process module 24 such as the process chamber by a robot arm 211 of the VTM robot 21. A finger 27 for transferring the wafer W may be coupled at a front of the robot arm 211, and the wafer W may be loaded on the finger 27 for being transferred from the TM 23 to the process module 24. An electrostatic chuck (ESC) 28 may be installed within the process module 24, and the wafer W may be fixed on the electrostatic chuck 28. When the wafer W is fixed on the electrostatic chuck 28, a wafer center CP1 should be coincident with a fixing surface center CP2 of the electrostatic chuck 28. The wafer W loaded on the finger 27 may be moved along a transferring path to be fixed on the fixing surface of the electrostatic chuck 28, and the wafer W needs to be moved so that the wafer center CP1 is coincident with the fixing surface center CP2 of the electrostatic chuck 28.

According to one embodiment of the present invention, the wafer W being transferred along the transferring path may be detected by the pair of component detecting sensors, and the center position of the wafer W may be calculated based on the detected information obtained by the pair of component detecting sensors 26a, 26b. The pair of component detecting sensors 26a, 26b may be installed at a body of the process chamber and installed at the transferring path of the wafer W. A plurality of component detecting sensors 26a, 25b may be installed, and each component detecting sensor 26a, 26b may be an optical sensor such as a laser sensor, an ultrasonic sensor or various sensors similar thereto, not limited to. The finger 27 may be transferred at a predetermined velocity along a predetermined path, and different parts of the wafer W may be detected by each component detecting sensor.

For example, a first point P1 and a second point P2 of the wafer W may be detected by the first component detecting sensor 26a. And also, a third and a fourth point P3, P4 of the wafer W may be detected by the second component detecting sensor 26b. A length that the wafer W passes through the first component detecting sensor 26a may be measured by detecting the first and second point P1, P2. And also, a length that the wafer W passes through the second component detecting sensor 26b may be measured by detecting the third and the fourth point P3, P4. The first and second component detecting sensor 26a, 26b may be disposed at both sides of a straight line connecting the center of the electrostatic chuck 27 and the center of the wafer W located at the transferring path. If the length between the first and second positions P1, P2 detected by the first component detecting sensor 26 is identical to the length between the third and fourth positions detected by the second component detecting sensor 26, then it can be considered that the center CP1 of the wafer W is moving along a straight line connecting a midpoint of the first and second component detecting sensor 26a, 26b and a fixing surface center CP2 of the electrostatic chuck 28. In contrast, if two lengths are different from each other, then it can be considered that the center CP1 of the wafer W is moving away from the connecting straight line. A deviating degree may be calculated from a difference between the lengths of two straight lines, and the wafer W position may be corrected in course of fixing the wafer W at the electrostatic chuck 28 based on the calculated difference value.

According to one proper embodiment of the present invention, the height between the wafer W and the reference surface may be measured by at least two component detecting sensors 26a, 26b, and heights of different parts of the wafer W may be measured by each component detecting sensor 26a, 26b. The wafer W needs to be moved under a parallel condition to the reference surface. If the heights detected by each component detecting sensor 26a, 26b are the same, then it can be seen that the wafer W is being moved in a horizontal condition. In contrast, If the height detected by each component detecting sensor 26a, 26b are different each other, it can be seen that the wafer W is being moved in a tilting condition. And a height adjustment of the wafer W or a correction to a tilt of wafer W may be performed. Various components fixed at the electrostatic chuck 28 may be detected by the component detecting sensors 26a, 26b.

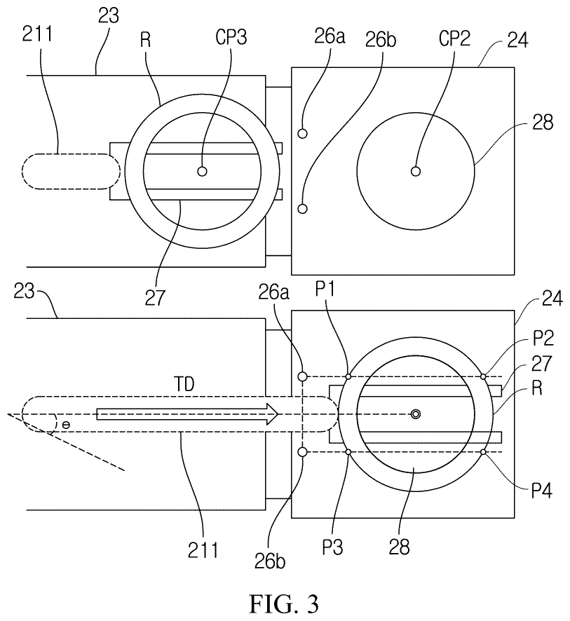

FIG. 3 shows other embodiment a system for determining a center position of a transferred semiconductor part according to the present invention.

Referring to FIG. 3, an edge ring, a cover ring or a focus ring R may be fixed at an edge of the electrostatic chuck 28, and the edge ring R may have a circular ring shape or a loop shape. The first and the second component detecting sensors 26a, 25b may be disposed at the process module 24, and a center CP3 of the edge ring R loaded on the finger 27 for transferring may pass between the first and the second component detecting sensors 26a, 26b. The first and second point P1, P2 may be detected by the first component detecting sensor 26a, and the third and fourth point P3, P4 may be detected by the second component detecting sensors 26b. And then the distance between the first and second point P1, P2, and the distance between the third and fourth point P3, P4 may be calculated. And it may be judged based on the calculated distance that the edge ring R is being transferred along a predetermined path. And also, four heights of four points P1, P2, P3, P4 may be measured by each component detecting sensor 26a, 26b, thereby the height or the inclination of the transferred edge ring R with respect to the reference surface may be measured.

The edge ring R has an inner diameter and an outer diameter, and the size of the inner diameter can be calculated based on the obtained detection information. And also, the outer diameter size of the edge ring R may be calculated based on the information detected by the first and second component detecting sensor 26a, 26b. Accordingly, the thickness of the edge ring R can be measured. And also, the center position of the inner diameter and outer diameter may be calculated. If the center position of the inner diameter is not identical to that of the outer diameter, then it can be seen that the thickness of the edge ring R is not uniform around the circumference. The center position of the edge ring R calculated from the information detected by the first and second component detecting sensor 26a, 26b may be applied to, for example, a control knob or the like. For example, the center position CP3 of the edge ring R may be intentionally deviated from the fixing surface center CP2 of the electrostatic chuck 28 for a uniformity of a temperature profile or a plasma density profile. In this case, the position of the edge ring R in the electrostatic chuck 28 may be determined using the calculated center coordinate of the edge ring R. The center position CP3 of the edge ring R detected by the first and second component detecting sensor 26a, 26b or a center position of a semiconductor part transferred to the electrostatic chuck 28 from the transferring module 23 may be utilized in various ways, but not limited to.

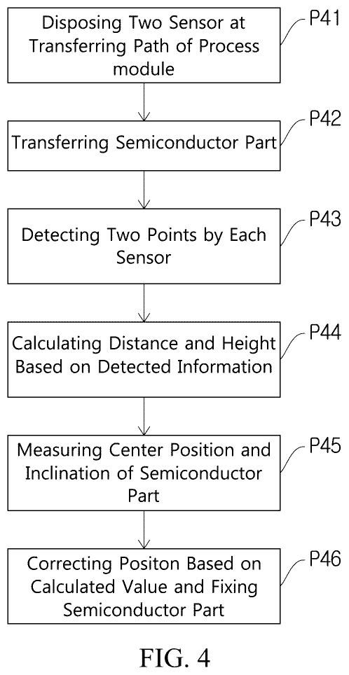

FIG. 4 shows an embodiment of a process for fixing a semiconductor part at a designated position after the semiconductor part is transferred from a transferring module to a process module.

Referring to FIG. 4, a process for fixing a semiconductor part such as a wafer or an edge ring at a designated position comprises disposing at least two component detecting sensors in a transferring path of a process module P41; transferring the semiconductor part such as the wafer or the edge ring along the transferring path P42; detecting two points of the semiconductor part using each component detecting sensor P43; calculating a distance or a height based on the detected information P44; determining a center position, a height or an inclination of the semiconductor part from the calculated distance and the height P45; correcting the position of the semiconductor part based on the determined information and fixing the semiconductor part at a designated position P46.

The component detecting sensors may be placed at the same area as the area where the semiconductor part is fixed, and for example, the component may be placed an entering portion through which the wafer or the edge ring inputs within the process chamber where an electrostatic chuck is installed, but not limited to. The component detecting sensors may be various kinds of sensors including an optical sensor capable of detecting the semiconductor part. The component detecting sensors may be disposed at the transferring path along which the semiconductor part is transferring, for example, the component detecting sensors may be placed below or above the transferring path for detecting the semiconductor part transferred along the transferring path. When the semiconductor part is transferred along the transferring path P42, the semiconductor part may be detected by the at least one component detecting sensor placed at the transferring path P43. Different parts of the semiconductor part may be detected by each component detecting sensor, and specifically different two position of the semiconductor part may be detected by each component detecting sensor P43. The shape and transferring velocity of the semiconductor part may be determined in advance, and if times when two positions are detected are measured, then the distance between two points may be calculated. And the component detecting sensor may be a distance detecting sensor, and the component heights to the reference surface may be detected by the component detecting sensor. The midpoint of the straight line connecting two component detecting sensors may be set as a reference point, and a straight line connecting the reference point and the center of the electrostatic chuck where the semiconductor part is fixed may be set as a reference line. If the distances of each two points is calculated by two component detecting sensors and the heights at different locations are detected, then four points may be designated as three dimensional coordinate (R, θ, Z) based on the reference point and reference line, and the component distance to the transferring direction, the component rotational angle based on the transferring direction and the component height from the reference surface may be calculated. And the component center point, the component height from the reference surface or the component inclination may be calculated from the three dimensional coordinate (R, θ, Z). If the center position of the semiconductor part, the height of the semiconductor part or the inclination of the semiconductor part is calculated in this way, then the fixed position may be corrected based on the calculating result, and the semiconductor part may be fixed at the corrected position P46. The center position of the semiconductor part, the height or the inclination can be calculated in various ways, but not limited to. And also, such detected information of the component detecting sensors may be applied to a preventive management of a transferring arm or the finger.

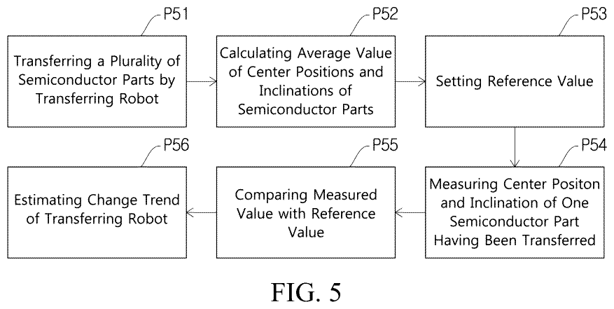

FIG. 5 shows an embodiment of a method for managing an operating error of a transferring robot according to the present invention.

Referring to FIG. 5, a method for managing an operation error of a transferring robot comprises transferring a plurality of semiconductor parts using a transferring robot P51; calculating an average value of a center position, a height and an inclination of the plurality of semiconductor parts P52; setting a reference value based on the average value P53; transferring one semiconductor part and measuring a center position, a height and an inclination P54; comparing the measured values with the reference value P55; and estimating a change trend of transferring function occurring in the transferring robot according to the comparing result P56.

The plurality of semiconductor parts may be transferred, and the semiconductor parts may have different sizes P51. For example, a plurality of wafers with different diameters may be transferred. The transferred components may be detected by the component detecting components, and the center position, the height and the inclination of each semiconductor part may be calculated. And then, the average value of the center position, the height and the inclination of the plurality semiconductor part may be calculated. The calculated average value may be set as the reference value P53, and the average value may become an error range of the center position, the height and the inclination that can be generated in course of transferring the semiconductor parts. The calculated average value in this way may be set as the reference value P53. One semiconductor part may be transferred to the process chamber, and the center position, the height and the inclination of the semiconductor part may be calculated P54. And the calculated value may be compared with the center position range, the height range and the inclination range set as the reference value P55. If the calculated center position, the height or the inclination is out of the range set as the reference value and the error out of the range appears continuously or frequently, then it can be considered that the transferring function of the transferring robot have changed P56. Thereby, the transferring function needs to be reset, or the transferring function needs to be adjusted again. In this way, the component detecting sensors may be applied to a preventive management of various apparatuses including the transferring robot.

What is claimed is:

1. A method for determining a center position of a transferred semiconductor part comprising:
disposing at least one pair of component detecting sensors at a transferring path of the semiconductor part;
detecting different portions of the semiconductor part by each component detecting sensor;
calculating a centering position of the semiconductor part based on the detected different portions; and
fixing the semiconductor part at a designated position based on the calculating result.

2. The method according to claim 1, wherein the at least one pair of component detecting sensors are disposed at a process chamber where the semiconductor part is secured.

3. The method according to claim 1, wherein the semiconductor part is a wafer or an edge ring.

4. The method according to claim 1, wherein the different portions are located at both parts in a component bisector corresponding to the transferring path of the semiconductor part.

5. The method according to claim 1, wherein a height from a reference surface is measured by each component detecting sensor.

6. A system for determining a center position of a transferred semiconductor part, comprising:
a transferring robot for transferring the semiconductor part;
a pair of component detecting sensors disposed at a process chamber for a process of the semiconductor part; and
a component location determining module for determining a center position of the semiconductor part based on two pairs of positions of the semiconductor part detected by each component detecting sensor.

7. The system according to claim 6, wherein three dimensional coordinates R, 6, Z are determined by the component location determining module for calculating a distance along a transferring direction of the semiconductor part, a rotating angle based on the transferring direction, a height and an inclination.

8. The system according to claim 6, wherein the semiconductor part is a wafer or an edge ring, and the semiconductor part is transferred from a transferring module to a process chamber.
